(19) United States
(12) Patent Application Publication
(10) Pub. No.: US 2026/0173987 A1
(43) Pub. Date: Jun. 18, 2026

(54) SEMICONDUCTOR PACKAGE HAVING LOW SIDE FIELD-EFFECT TRANSISTOR CHIPS OF DIFFERENT SIZES AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Rhys Philbrick, Los Gatos, CA (US); Madhur Bobde, Sunnyvale, CA (US); Long-Ching Wang, Cupertino, CA (US); Ji Pan, San Jose, CA (US); Zhiqiang Niu, Santa Clara, CA (US); Xiaobin Wang, San Jose, CA (US)

(73) Assignee: ALPHA AND OMEGA SEMICONDUCTOR INTERNATIONAL LP, TORONTO (CA)

(21) Appl. No.: 19/307,988

(22) Filed: Aug. 22, 2025

Related U.S. Application Data
(63) Continuation-in-part of application No. 18/984,370, filed on Dec. 17, 2024.

(51) Int. Cl. H01L 23/495; H01L 21/56; H01L 23/00; H01L 23/31; H01L 25/00

(52) U.S. Cl. CPC H10W 90/811; H10W 70/481; H10W 74/014; H10W 74/111; H10W 90/00; H10W 72/871; H10W 90/753; H10W 90/756; H10W 90/763

(57) ABSTRACT

A semiconductor package comprises a lead frame, a high side chip, a first low side chip, a second low side chip, a first metal clip, a second metal clip, an integrated circuit (IC), and a molding encapsulation. A method comprises the steps of providing a lead frame; mounting a high side chip, a first low side chip, and a second low side chip; mounting a first metal clip and a second metal clip; mounting an IC; forming a molding encapsulation; and applying a singulation process.

### CROSS-REFERENCE RO RELATED APPLICATIONS

This Patent Application is a Continuation-in-part application of a pending U.S. patent application Ser. No. 18/984,370 filed on Dec. 17, 2024. The Disclosure made in U.S. patent application Ser. No. 18/984,370 is hereby incorporated by reference.

### FIELD OF THE INVENTION

This invention relates generally to a semiconductor package and a method of making the same. More particularly, the present invention relates to the semiconductor package, having low side field-effect transistor (FET) chips of different sizes and the method of making the same.

### BACKGROUND OF THE INVENTION

US Patent Application Publication No. 2017/0047315 to Otremba et al. discloses a semiconductor power converter device having a first semiconductor power chip on a first carrier, a second semiconductor power chip on a second carrier, and a third semiconductor control IC chip over a contact clip. FIG. 1A of instant disclosure shows a conventional footprint of a single phase semiconductor power converter package 100. Each of the switch node voltage (VSWH) pins 110 of the semiconductor package 100 is electrically connected.

FIG. 1B is a footprint of a semiconductor package 150 in examples of the present disclosure. The VSWH pins are separated into a first one and more VSWH pins 160 and a second one and more VSWH pins 170 for a dual phases semiconductor power converter package. The dual phases semiconductor power converter package includes a first phase to operate in light load condition so as to facilitate light load efficiency and a second phase to operate in heavy load condition.

### SUMMARY OF THE INVENTION

The present invention discloses a semiconductor package comprises a lead frame, a high side chip, a first low side chip, a second low side chip, a first metal clip, a second metal clip, an integrated circuit (IC), and a molding encapsulation.

A method for fabricating a semiconductor package is also disclosed. The method comprises the steps of providing a lead frame; mounting a high side chip, a first low side chip, and a second low side chip; mounting a first metal clip and a second metal clip; mounting an IC; forming a molding encapsulation; and applying a singulation process.

### BRIEF DESCRIPTION OF THE DRAWINGS

FIG. 1A is a conventional footprint of a semiconductor package. FIG. 1B is a footprint of a semiconductor package in examples of the present disclosure.

FIG. 2A is a top perspective view and FIG. 2B is a bottom perspective view of a semiconductor package and FIG. 2AA is a top perspective view of another semiconductor package in examples of the present disclosure.

FIG. 3A is a top perspective view and FIG. 3B is an exploded plot of still another semiconductor package in examples of the present disclosure.

FIG. 4 is a flowchart of a process to develop a semiconductor package in examples of the present disclosure.

FIGS. 5A, 5B, 5C, 5D, 5E, 5F, and 5G show the process of FIG. 4 to fabricate the semiconductor package in examples of the present disclosure.

### DETAILED DESCRIPTION OF THE INVENTION

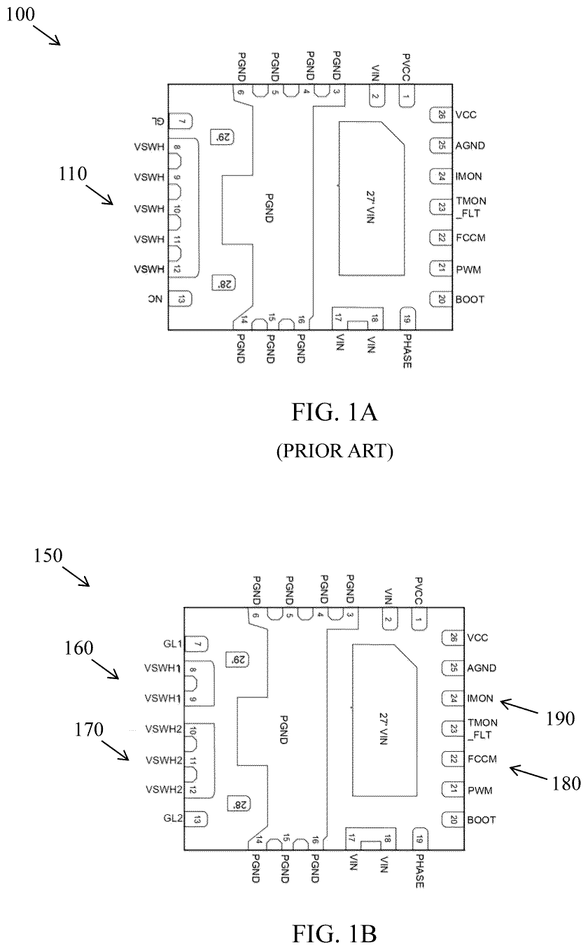

FIG. 1A is a conventional footprint of a semiconductor package 100. Each of the VSWH pins 110 of the semiconductor package 100 is electrically connected. FIG. 1B is a footprint of a semiconductor package 150 in examples of the present disclosure. The VSWH pins are separated into a first one and more VSWH pins 160 and a second one and more VSWH pins 170 so as to facilitate light load efficiency. The electrical operation includes two phases: phase 1 (a mini-phase) and phase 2. The phase 1 provides excellent light load efficiency. The phase 2 is deactivated when the forced continuous conduction mode (FCCM) 180 is low and the electrical current is low. In a discontinuous current mode (DCM) operation, the phase 2 is off until an electrical limit is reached or the FCCM 180 is applied. A current monitor output signal (IMON) 190 offset is improved when the phase 2 is off. In examples of the present disclosure, a resistance of the phase 1 is three times of that of the phase 2. An inductance of the phase 1 is two times to six times of that of the phase 2.

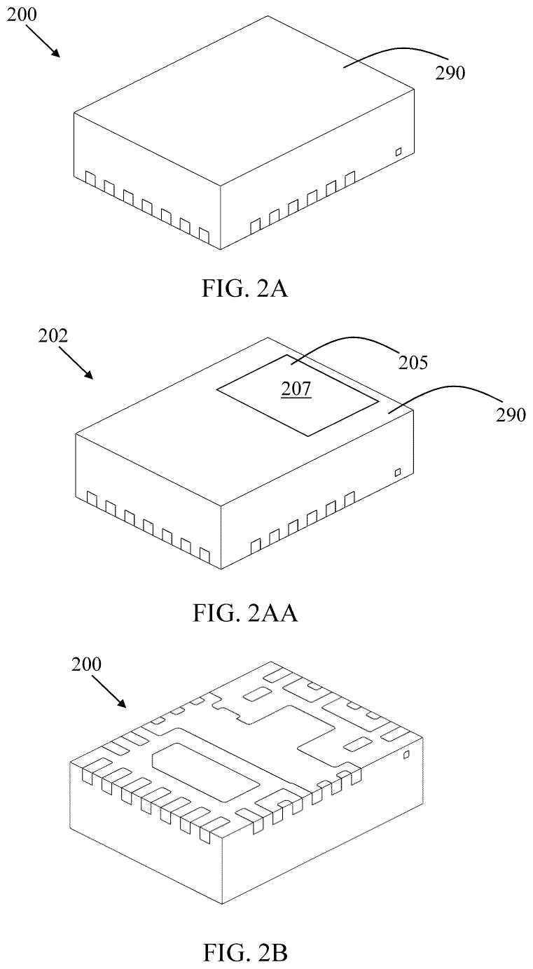

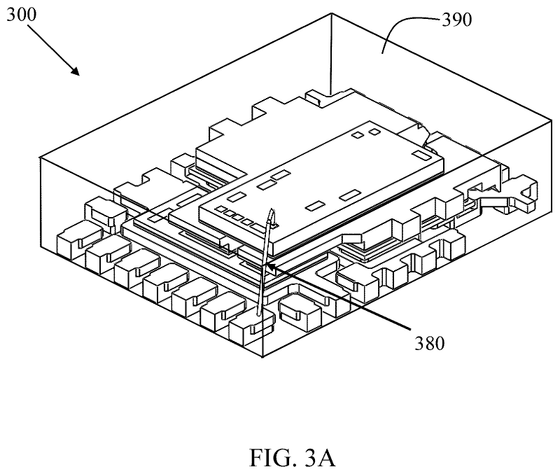

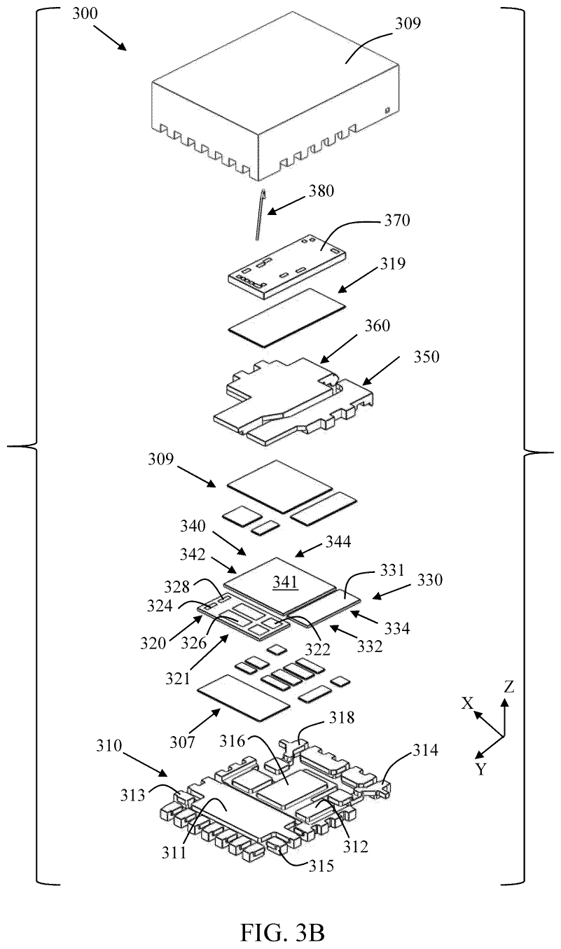

FIG. 2A is a top perspective view and FIG. 2B is a bottom perspective view of a semiconductor package 200 in examples of the present disclosure. FIG. 2AA is a top perspective view of a semiconductor package 202. FIG. 3A is a top perspective view and FIG. 3B is an exploded plot of another semiconductor package 300 in examples of the present disclosure. The semiconductor package 300 is the same as the semiconductor package 200 except that the semiconductor package 300 excludes a metal slug 205, shown in FIG. 2AA, of the semiconductor package 200. In FIG. 3A, the molding encapsulation 390 is shown in transparent. In examples of the present disclosure, the semiconductor package 200 is of a rectangular prism shape.

Referring now to FIG. 3B, the semiconductor package 300 comprises a lead frame 310, a high side chip 320, a first low side chip 330, a second low side chip 340, a first metal clip 350, a second metal clip 360, an IC 370, and a molding encapsulation 390. In one example, the semiconductor package 300 is a quad flat no-lead (QFN) package. In another example, the semiconductor package 300 is a driver and MOSFET module (DrMOS). Here, MOSFET is metal-oxide-semiconductor field-effect transistor. In examples of the present disclosure, the high side chip 320 is a MOSFET chip of a first rectangular prism shape. The first low side chip 330 is a MOSFET chip of a second rectangular prism shape. The second low side chip 340 is a MOSFET chip of a third rectangular prism shape.

The lead frame 310 comprises a high side drain pad 311, an optional first high side gate lead 313, an optional second high side gate lead 313, a first low side source pad 312, a first low side gate lead 314, a second low side source pad 316, and a second low side gate lead 318. The first low side source pad 312 and the second low side source pad 316 are connected together and both disposed alongside with the high side drain pad 511 and separate from the high side drain pad 511.

In examples of the present disclosure, a first solder layer 307 is between the lead frame 310 and the high side chip 320, the first low side chip 330, and the second low side chip 340.

The high side chip 320 is attached to the high side drain pad 311. The high side chip 320 comprises a first source electrode 322, a first gate electrode 324, a second source electrode 326 electrically isolated from the first source electrode 322, and a second gate electrode 328 electrically isolated from the first gate electrode 324 on a front surface of the high side chip 320, and a drain electrode 321 on a back surface of the high side chip 320.

The first low side chip 330 is flipped and attached to the first low side source pad 312. The first low side chip 330 comprises a source electrode 332 and a gate electrode 334 on a front surface of the first low side chip 330, and a drain electrode 331 on a back surface of the first low side chip 330. The gate electrode 334 of the first low side chip 330 is connected to the first low side gate lead 314 of the lead frame 310.

The second low side chip 340 is flipped and attached to the second low side source pad 316. The second low side chip 340 comprises a source electrode 342 and a gate electrode 344 on a front surface of the second low side chip 340, and a drain electrode 341 on a back surface of the second low side chip 340. The gate electrode 344 of the second low side chip 340 is connected to the second low side gate lead 318 of the lead frame 310.

In examples of the present disclosure, a second solder layer 309 is between the first and second metal clips 350 and 360, and the high side chip 320, the first low side chip 330, and the second low side chip 340.

The first metal clip 350 connects the first source electrode 322 of the high side chip 320 to the drain electrode 331 of the first low side chip 330. The second metal clip 360 connects the second source electrode 326 of the high side chip 320 to the drain electrode 341 of the second low side chip 340. The IC 370 may be attached to both or one of the first metal clip 350 and the second metal clip 360. In one example of this disclosure, the IC 370 is attached to the first metal clip 350. In examples of the present disclosure, a third solder layer 319 is between the IC 370 and the first and second metal clips 350 and 360.

The molding encapsulation 390 encloses the high side chip 320, the first low side chip 330, the second low side chip 340, the first metal clip 350, the second metal clip 360, the IC 370, and a majority portion of the lead frame 310. A majority is larger than 50%. In examples of the present disclosure, bottom surfaces of the lead frame 310 are exposed from the molding encapsulation 390.

The semiconductor package 300 further comprises a plurality of bond wires 380 of FIG. 3A electrically connecting the IC 370 to the high side chip 320, the first low side chip 330, the second low side chip 340, and the lead frame 310. The molding encapsulation 390 further encloses the plurality of bond wires 380. The first gate electrode 324 and the second gate electrode 328 of the high side chip 320 are electrically connected to the IC 370.

In examples of the present disclosure, a size of the first low side chip 330 is smaller than a size of the second low side chip 340. In one example, the size of the first low side chip 330 is in a range from 30% to 35% of the size of the second low side chip 340. In another example, the first low side chip 330 and the second low side chip 340 are of a same thickness. The first low side chip 330 and the second low side chip 340 are of a same length (for example, 1.54 mm). A width of the first low side chip 330 is in a range from 30% to 35% of a width of the second low side chip 340. In one example, the width of the first low side chip 330 is 0.6 mm. The width of the second low side chip 340 is 1.74 mm.

In examples of the present disclosure, the first low side chip 330 and the second low side chip 340 are aligned horizontally (X-direction).

In examples of the present disclosure, the semiconductor package 200 of FIG. 2AA further comprises a metal slug 205 attached to the second metal clip 360 of FIG. 3B. The molding encapsulation 290 of FIG. 2AA further encloses a majority portion of the metal slug 205. A majority is larger than 50%. A top surface 207 of the metal slug 205 is exposed from the molding encapsulation 290 so as to facilitate heat dissipation.

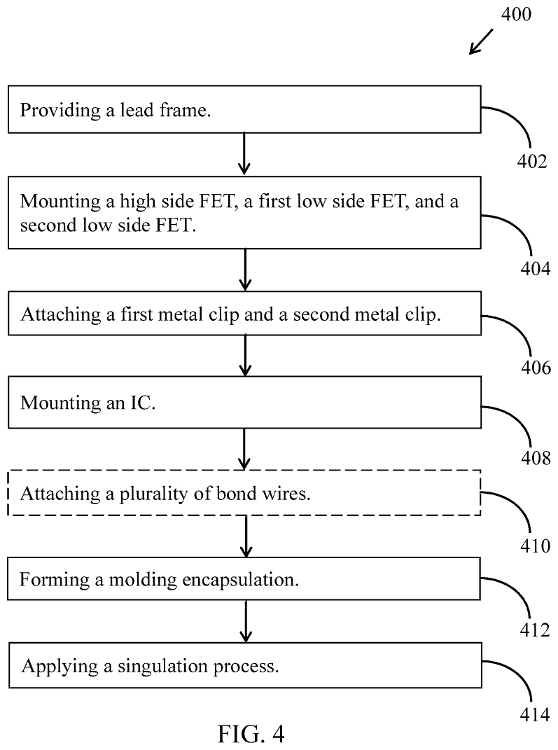

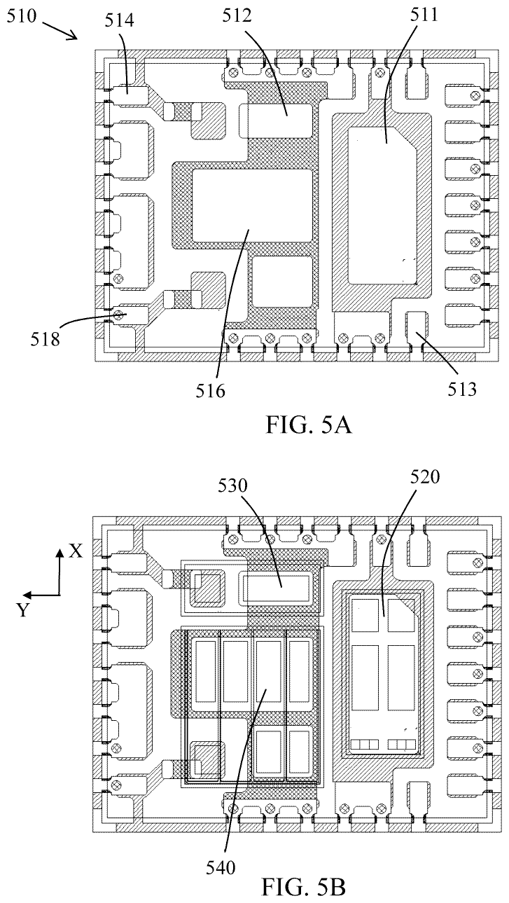

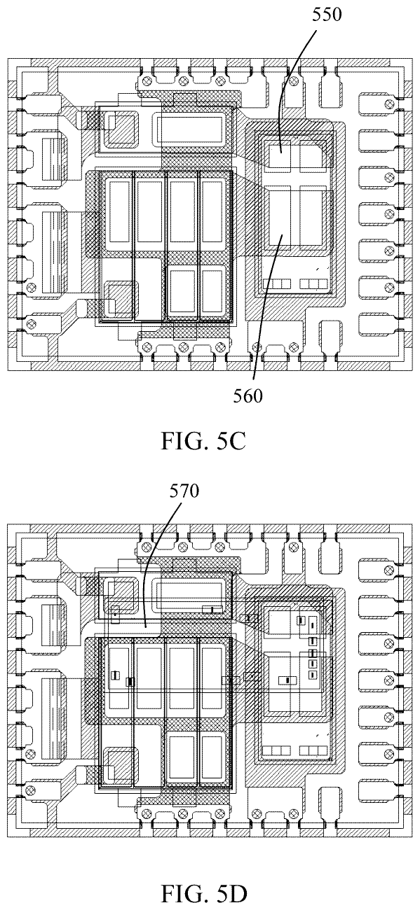

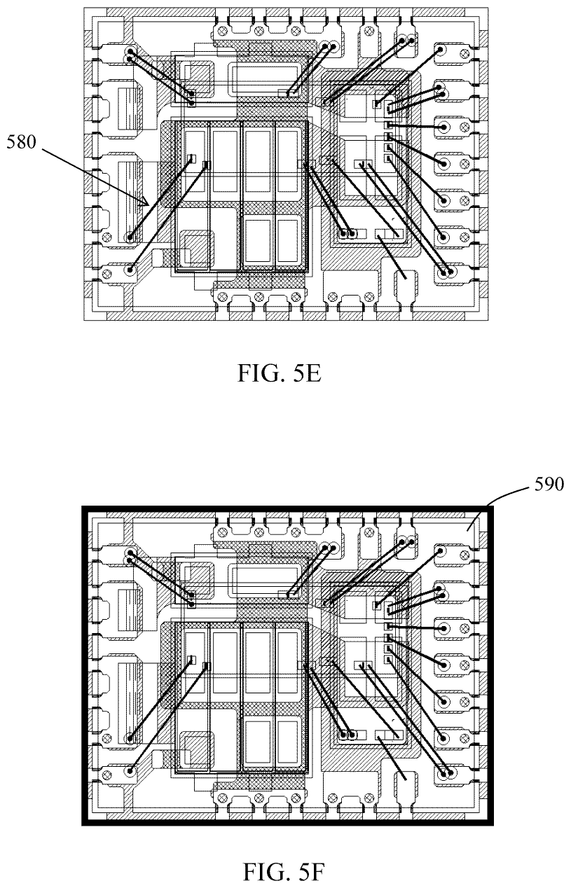

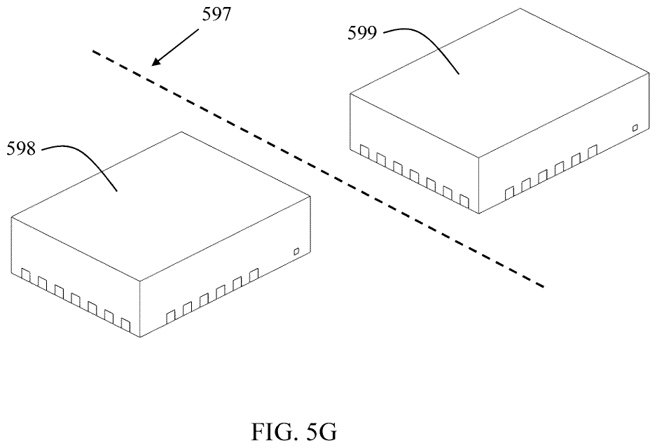

FIG. 4 is a flowchart of a process 400 to develop a semiconductor package in examples of the present disclosure. The process 400 may start from block 402. A plurality of semiconductor packages may be fabricated at the same time. In one example, FIG. 5G shows 2 semiconductor packages are fabricated at the same time. The number of semiconductor packages, fabricated at the same time, may vary. For simplicity, FIGS. 5A-5F show top views the process steps for fabricating a single semiconductor package. FIG. 5G shows a top perspective view.

In block 402, referring now to FIG. 5A, a lead frame 510 is provided. The lead frame 510 comprises a high side drain pad 511 in substantial rectangular shape, one or more optional high side gate leads 513, a first low side source pad 512, a first low side gate lead 514 adjacent the first low side source pad 512, a second low side source pad 516, and a second low side gate lead 518 adjacent the first low side source pad 512. The first low side source pad 512 and the second low side source pad 516 are connected together and both disposed alongside with the high side drain pad 511 and separate from the high side drain pad 511. The first low side gate lead 514 is disposed at a first cutoff portion of the first low side source pad 512 and the second low side gate lead 518 is disposed at a second cutoff portion of the second low side source pad 516. In examples of the present disclosure, the first low side gate lead 514 and the second low side gate lead 518 are separated from the high side drain pad 511 by the first low side source pad 512 and the second low side source pad 516 respectively. Alternatively, the first low side gate lead 514 and/or the second low side gate lead 518 may be disposed between the high side drain pad 511 and the first low side source pad 512 and/or the second low side source pad 516 respectively Block 402 may be followed by block 404.

In block 404, referring now to FIG. 3B and FIG. 5A, a high side chip 520, a first low side chip 530, and a second low side chip 540 of FIG. 5A are attached to the lead frame 510 by a first solder layer 307 of FIG. 3B. The high side chip 520 is attached to the high side drain pad 511. The high side chip 520 comprises a first source electrode 322, a first gate electrode 324, a second source electrode 326, and a second gate electrode 328 of FIG. 3B on a front surface of the high side chip 520, and a drain electrode 321 of FIG. 3B on a back surface of the high side chip 520.

The first low side chip 530 is flipped and attached to the first low side source pad 512. The first low side chip 530 comprises a source electrode 332 and a gate electrode 334 of FIG. 3B on a front surface of the first low side chip 530, and a drain electrode 331 of FIG. 3B on a back surface of the first low side chip 530. The gate electrode 334 of the first low side chip 530 is connected to the first low side gate lead 514 of the lead frame 510.

The second low side chip 540 is flipped and attached to the second low side source pad 516. The second low side chip 540 comprises a source electrode 342 and a gate electrode 344 of FIG. 3B on a front surface of the second low side chip 540, and a drain electrode 341 of FIG. 3B on a back surface of the second low side chip 540. The gate electrode 344 of the second low side chip 540 is connected to the second low side gate lead 518 of the lead frame 510.

In examples of the present disclosure, the first low side chip 530 and the second low side chip 540 are aligned vertically (X-direction). A size of the first low side chip 530 may be smaller than a size of the second low side chip 540. In one example, the size of the first low side chip 530 is in a range from 30% to 35% of the size of the second low side chip 540. In another example, the first low side chip 530 and the second low side chip 540 are of a same thickness. The first low side chip 530 and the second low side chip 540 are of a same length (for example, 1.54 mm). A width of the first low side chip 530 is in a range from 30% to 35% of a width of the second low side chip 540. In one example, the width of the first low side chip 530 is 0.6 mm. The width of the second low side chip 540 is 1.74 mm. Block 404 may be followed by block 406.

In block 406, referring now to FIG. 3B and FIG. 5C, a first metal clip 550 and a second metal clip 560 of FIG. 5C are mounted by a second solder layer 309 of FIG. 3B. The first metal clip 550 electrically connects the first source electrode 322 of FIG. 3B of the high side chip 520 to the drain electrode 331 of FIG. 3B of the first low side chip 530. The second metal clip 560 electrically connects the second source electrode 326 of FIG. 3B of the high side chip 520 to the drain electrode 341 of FIG. 3B of the second low side chip 540. Block 406 may be followed by block 408.

In block 408, referring now to FIG. 5D, an IC 570 is mounted. As shown, the IC 570 may attach to the first metal clip 550 and the second metal clip 560. Alternatively, the IC 570 may attach only to the first metal clip 550 or the second clip 560. Alternatively, the semiconductor package in FIGS. 2A, 2AA and 2B may include the high side chip 520, the first low side chip 530, and the second low side chip 540 without the IC 570. In that case the step described in block 408 may be skipped.

In examples of the present disclosure, in block 408, an optional metal slug 205 of FIG. 1A is attached to the second metal clip 560. Block 408 may be followed by optional block 410 or block 412.

In block 410, referring now to FIG. 5E, a plurality of bond wires 580 are applied. The plurality of bond wires 580 electrically connect the IC 570 to the high side chip 520, the first low side chip 530, the second low side chip 540, and the lead frame 510. In one example, the first gate electrode 324 and the second gate electrode 328 of FIG. 3B of the high side chip 520 are electrically connected to the IC 570 by direct bond wire connections between the high side chip 520 and the IC 570. In another example, a first pair of bond wires connect the first high side gate lead to the first gate electrode 324 on the high side chip 520 and the IC 570 respectively, and a second pair of bond wires connect the second high side gate lead to the second gate electrode 328 on the high side chip 520 and the IC 570 respectively. Block 410 may be followed by block 412.

In block 412, referring now to FIG. 5F, a molding encapsulation 590 is formed. The molding encapsulation 590 encloses the high side chip 520, the first low side chip 530, the second low side chip 540, the first metal clip 550, the second metal clip 560, the IC 570, the plurality of bond wires 580, and a majority portion of the lead frame 310. A majority is larger than 50%. In examples of the present disclosure, bottom surfaces of the lead frame 510 are exposed from the molding encapsulation 590. A top surface 207 of the metal slug 205 is also exposed from the molding encapsulation 290 as shown in FIG. 2AA so as to facilitate heat dissipation. Block 412 may be followed by block 414.

In block 414, referring now to FIG. 5G, a singulation process 597 is applied so as to separate the semiconductor package 598 from adjacent semiconductor packages 599. In examples of the present disclosure, each of the semiconductor package 598 and the adjacent semiconductor packages 599 is of a rectangular prism shape. In one example, each of the semiconductor package 598 and the adjacent semiconductor packages 599 is a QFN package. In another example, each of the semiconductor package 598 and the adjacent semiconductor packages 599 is a DrMOS with two phases.

Those of ordinary skill in the art may recognize that modifications of the embodiments disclosed herein are possible. For example, a number of the plurality of bond wires 580 may vary. Other modifications may occur to those of ordinary skill in this art, and all such modifications are deemed to fall within the purview of the present invention, as defined by the claims.

1. A semiconductor package comprising:
a lead frame comprising:
a high side drain pad,
a first low side source pad,
a first low side gate lead,
a second low side source pad, and
a second low side gate lead,
a high side chip attached to the high side drain pad, the high side chip comprising:
a first source electrode, a first gate electrode, a second source electrode, and a second gate electrode on a front surface of the high side chip, and
a drain electrode on a back surface of the high side chip,
a first low side chip being flipped and attached to the first low side source pad, the first low side chip comprising:
a source electrode and a gate electrode on a front surface of the first low side chip, and
a drain electrode on a back surface of the first low side chip,
a second low side chip being flipped and attached to the second low side source pad, the second low side chip comprising:
a source electrode and a gate electrode on a front surface of the second low side chip, and
a drain electrode on a back surface of the second low side chip,
a first metal clip connecting the first source electrode of the high side chip to the drain electrode of the first low side chip,
a second metal clip connecting the second source electrode of the high side chip to the drain electrode of the second low side chip, and
a molding encapsulation enclosing the high side chip, the first low side chip, the second low side chip, the first metal clip, the second metal clip, the IC, and a majority portion of the lead frame;
wherein the gate electrode of the first low side chip is connected to the first low side gate lead of the lead frame; and
wherein the gate electrode of the second low side chip is connected to the second low side gate lead of the lead frame.

2. The semiconductor package of claim 1 further comprising an integrated circuit (IC) attached to the first metal clip.

3. The semiconductor package of claim 2 further comprising a metal slug attached to the second metal clip,
wherein the molding encapsulation further encloses a majority portion of the metal slug; and
wherein a top surface of the metal slug is exposed from the molding encapsulation.

4. The semiconductor package of claim 2 further comprising a plurality of bond wires connecting the IC to the high side chip, the first low side chip, the second low side chip, and the lead frame,
wherein the molding encapsulation further encloses the plurality of bond wires; and
wherein the first gate electrode and the second gate electrode of the high side chip are electrically connected to the IC.

5. The semiconductor package of claim 2, wherein a size of the first low side chip is smaller than a size of the second low side chip.

6. The semiconductor package of claim 5, wherein the size of the first low side chip is in a range from 30% to 35% of the size of the second low side chip.

7. The semiconductor package of claim 5, wherein the first low side chip and the second low side chip are of a same thickness;
wherein the first low side chip and the second low side chip are of a same length; and
wherein a width of the first low side chip is in a range from 30% to 35% of a width of the second low side chip.

8. The semiconductor package of claim 1, wherein the first low side chip and the second low side chip are aligned horizontally.

9. The semiconductor package of claim 1, wherein the semiconductor package is a quad flat no-lead (QFN) package.

10. The semiconductor package of claim 1, wherein the first low side source pad and the second low side source pad are connected together.

11. A method for fabricating a semiconductor package, the method comprising the steps of:
providing a lead frame comprising:
a high side drain pad,
a first low side source pad,
a first low side gate lead adjacent the first low side source pad,
a second low side source pad, and
a second low side gate lead adjacent the first low side source pad;
mounting a high side chip on the high side drain pad, mounting a first low side chip on the first low side source pad, and mounting a second low side chip on the second low side source pad, the first low side chip being flipped, the second low side chip being flipped, the high side chip comprising:
a first source electrode, a first gate electrode, a second source electrode, and a second gate electrode on a front surface of the high side chip, and
a drain electrode on a back surface of the high side chip,
the first low side chip comprising:
a source electrode and a gate electrode on a front surface of the first low side chip, and
a drain electrode on a back surface of the first low side chip; and
the second low side chip comprising:
a source electrode and a gate electrode on a front surface of the second low side chip, and
a drain electrode on a back surface of the second low side chip;
mounting a first metal clip and mounting a second metal clip, the first metal clip connecting the first source electrode of the high side chip to the drain electrode of the first low side chip, and the second metal clip connecting the second source electrode of the high side chip to the drain electrode of the second low side chip;
mounting an integrated circuit (IC) on the first metal clip and the second metal clip;
forming a molding encapsulation enclosing the high side chip, the first low side chip, the second low side chip, the first metal clip, the second metal clip, the IC, and a majority portion of the lead frame; and
applying a singulation process separating the semiconductor package from adjacent semiconductor packages.

12. The method of claim 11, wherein the step of mounting the IC comprises the sub-steps of:
mounting a metal slug on the first metal clip,
wherein the molding encapsulation further encloses a majority portion of the metal slug; and
wherein a top surface of the metal slug is exposed from the molding encapsulation.

13. The method of claim 11, after the step of mounting the IC, further comprising the step of:
applying a plurality of bond wires connecting the IC to the high side chip, the first low side chip, the second low side chip, and the lead frame,
wherein the molding encapsulation further encloses the plurality of bond wires; and
wherein the first gate electrode and the second source electrode of the high side chip are electrically connected to the IC.

14. The method of claim 11, wherein a size of the first low side chip is smaller than a size of the second low side chip.

15. The method of claim 14, wherein the size of the first low side chip is in a range from 30% to 35% of the size of the second low side chip.

16. The method of claim 15, wherein the first low side chip and the second low side chip are of a same thickness;
wherein the first low side chip and the second low side chip are of a same length; and
wherein a width of the first low side chip is in a range from 30% to 35% of a width of the second low side chip.

17. The method of claim 11, wherein the first low side chip and the second low side chip are aligned horizontally.

18. The method of claim 11, wherein the semiconductor package is a quad flat no-lead (QFN) package.

19. The method of claim 11, wherein the semiconductor package is a driver and MOSFET module (DrMOS).

20. The method of claim 11, wherein the first low side source pad and the second low side source pad are connected together.
